(19) United States
(12) Patent Application Publication
(10) Pub. No.: US 2024/0385582 A1
(43) Pub. Date: Nov. 21, 2024

(54) CONTROL DEVICE, SEMICONDUCTOR MANUFACTURING SYSTEM, AND CONTROL METHOD OF SEMICONDUCTOR MANUFACTURING APPARATUS

(71) Applicant: Tokyo Electron Limited, Tokyo (JP)

(72) Inventors: Kiminari SAKAGUCHI, Koshi City (JP); Takayuki MASAKI, Koshi City (JP); Hirofumi ETOU, Koshi City (JP); Kouji OKAMURA, Koshi City (JP); Wataru FUNAKOSHI, Koshi City (JP); Hironari MURASHIMA, Koshi City (JP)

(21) Appl. No.: 18/658,527

(22) Filed: May 8, 2024

(30) Foreign Application Priority Data
May 19, 2023 (JP) 2023-083091

(51) Int. Cl. G05B 19/048; H01L 21/67; H01L 21/677

(52) U.S. Cl. CPC G05B 19/048; H01L 21/67253; H01L 21/67763; G05B 2219/45032

(57) ABSTRACT

A control device controls the semiconductor manufacturing apparatus having modules based on an operation from a user on an operation terminal displaying an operation screen of the semiconductor manufacturing apparatus. The semiconductor manufacturing apparatus includes: ports to which the operation terminal is to be connected; and detectors detecting the operation terminal connected to the ports, the ports serving as the detectors or the detectors being provided around the ports. The control device stores restriction information, the restriction information indicating controllable modules corresponding to the detectors in units of the detector; and when the operation terminal is connected to one of the ports and the operation terminal is detected via the corresponding detector, transmits screen information about the operation screen to the connected operation terminal based on the restriction information, the screen information including information indicating the controllable modules corresponding to the detector used for the detection.

### CROSS REFERENCE TO RELATED APPLICATIONS

This application is based upon and claims the benefit of priority of the prior Japanese Patent Application No. 2023-83091, filed in Japan on May 19, 2023, the entire contents of which are incorporated herein by reference.

### TECHNICAL FIELD

This disclosure relates to a control device, a semiconductor manufacturing system, and a control method of a semiconductor manufacturing apparatus.

### BACKGROUND

Japanese Laid-open Patent Publication No. 2022-41233 discloses a semiconductor manufacturing system having: a local operation terminal displaying an apparatus screen of a semiconductor manufacturing apparatus; one or more remote operation terminals connected to the semiconductor manufacturing apparatus over a network and displaying the apparatus screen; and a control device for controlling the semiconductor manufacturing apparatus based on an operation received from a user by the local operation terminal and the remote operation terminal displaying the apparatus screen.

### SUMMARY

An aspect of this disclosure is a control device for controlling a semiconductor manufacturing apparatus having a plurality of modules, the device for controlling the semiconductor manufacturing apparatus based on an operation from a user on an operation terminal displaying an operation screen of the semiconductor manufacturing apparatus, the semiconductor manufacturing apparatus including: a plurality of terminal connection ports to which the operation terminal is to be connected; and a plurality of detectors for detecting the operation terminal connected to the terminal connection ports, the terminal connection ports also serving as the detectors or the detectors being provided around the terminal connection ports, the control device being configured to: store module restriction information, the module restriction information indicating controllable modules corresponding to the detectors in units of the detector; and in a case of the operation terminal being connected to one of the terminal connection ports and the operation terminal being detected via the corresponding detector, transmit screen information about the operation screen to the connected operation terminal based on the module restriction information, the screen information including information indicating the controllable modules corresponding to the detector used for the detection.

### BRIEF DESCRIPTION OF THE DRAWINGS

FIG. 1 is an explanatory view illustrating the outline of a configuration of a semiconductor manufacturing system according to an embodiment.

FIG. 2 is an explanatory view illustrating the outline of the configuration on the front side of a coating and developing treatment apparatus as a semiconductor manufacturing apparatus included in the substrate treatment system in FIG. 1.

FIG. 3 is an explanatory view illustrating the outline of the configuration on the rear side of the coating and developing treatment apparatus as the semiconductor manufacturing apparatus included in the substrate treatment system in FIG. 1.

FIG. 4 is a functional block diagram of a controller of an operation terminal.

FIG. 5 is a functional block diagram of a controller of a control device.

FIG. 6 is a chart illustrating an example of module restriction information.

FIG. 7 is a chart illustrating an example of item restriction information.

FIG. 8 is a chart illustrating an example of specific item information.

FIG. 9 is a flowchart for explaining an example of a flow when an operation screen is displayed on a display of the operation terminal.

FIG. 10 is a chart illustrating an example of the operation screen.

FIG. 11 is a flowchart for explaining another example of the flow when the operation screen is displayed on the display of the operation terminal.

FIG. 12 is a chart illustrating an example of the operation screen.

FIG. 13 is an explanatory view illustrating the outline of an internal configuration of a cleaning apparatus as the semiconductor manufacturing apparatus.

### DETAILED DESCRIPTION

The maintenance and the like of various modules included in a semiconductor manufacturing apparatus may be performed via an operation terminal such as a tablet terminal. For example, a control device may control the modules of the semiconductor manufacturing apparatus based on an operation of an operator on the operation terminal displaying an operation screen of the semiconductor manufacturing apparatus.

However, this method has room for improvement in terms of safety. Specifically, for example, an operator on the front side of the semiconductor manufacturing apparatus may not be aware of an operator on the rear side of the semiconductor manufacturing apparatus. Therefore, the operator on the front side of the semiconductor manufacturing apparatus may operate the operation terminal so that the module on the rear side of the semiconductor manufacturing apparatus operates. If the module on the rear side operates unexpectedly, components of the module or liquid to be used by the module may come into contact with the operator on the rear side.

Hence, the technique according to this disclosure improves the safety in the case of controlling the semiconductor manufacturing apparatus based on the operation of the operator on the operation terminal.

Hereinafter, a control device, a semiconductor manufacturing system, and a control method of a semiconductor manufacturing apparatus according to embodiments will be explained with reference to the drawings. Note that, in the description and the drawings, elements having substantially the same functional configurations are denoted by the same reference signs to omit duplicate explanations.

### <Semiconductor Manufacturing System>

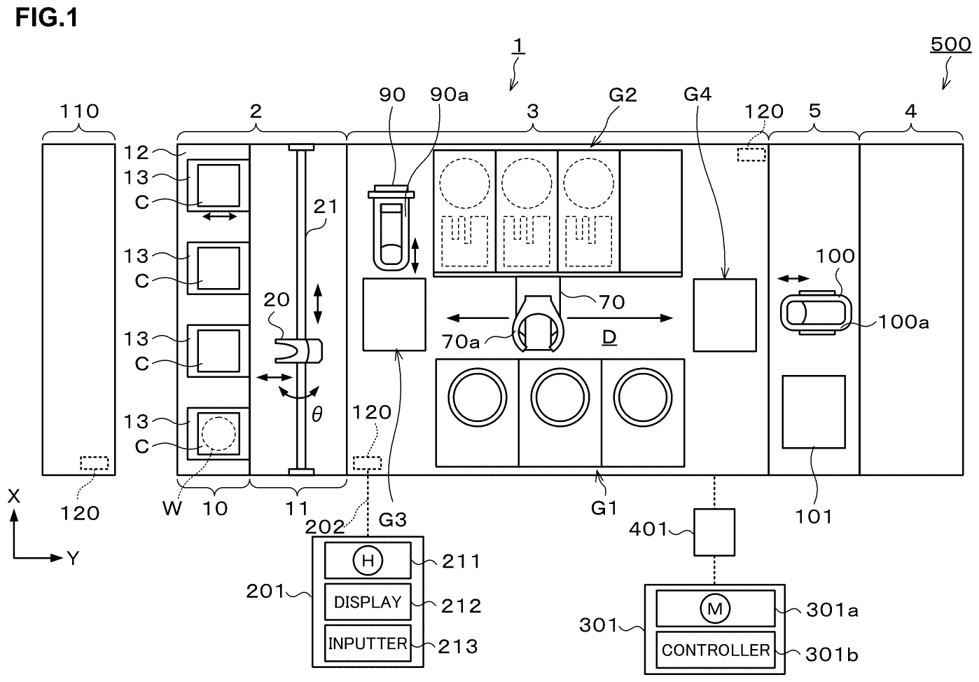

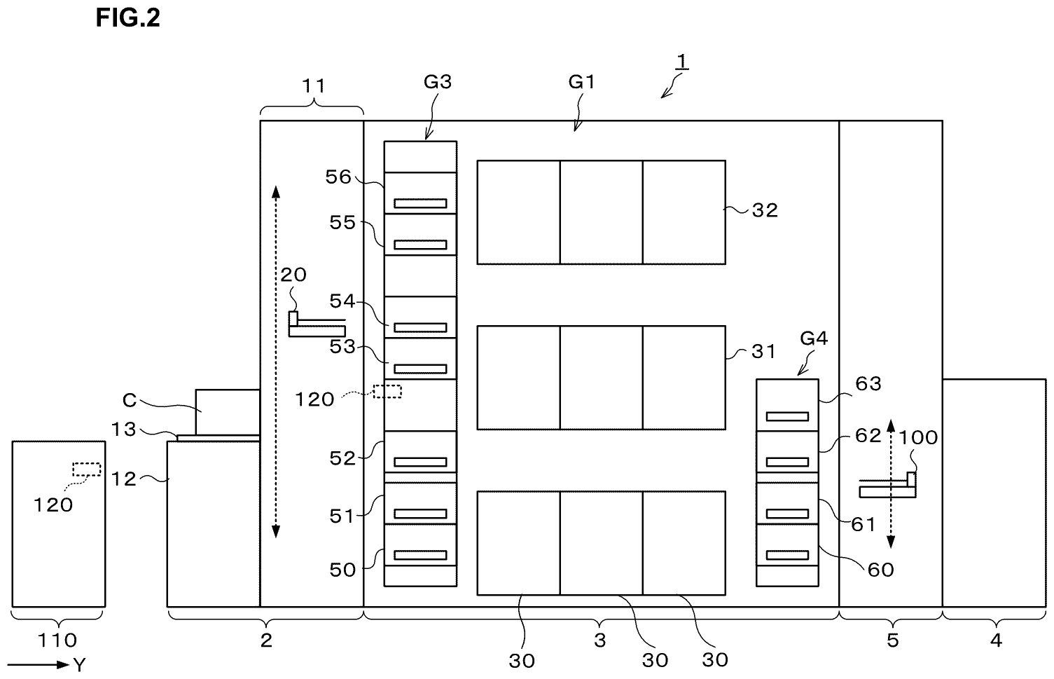

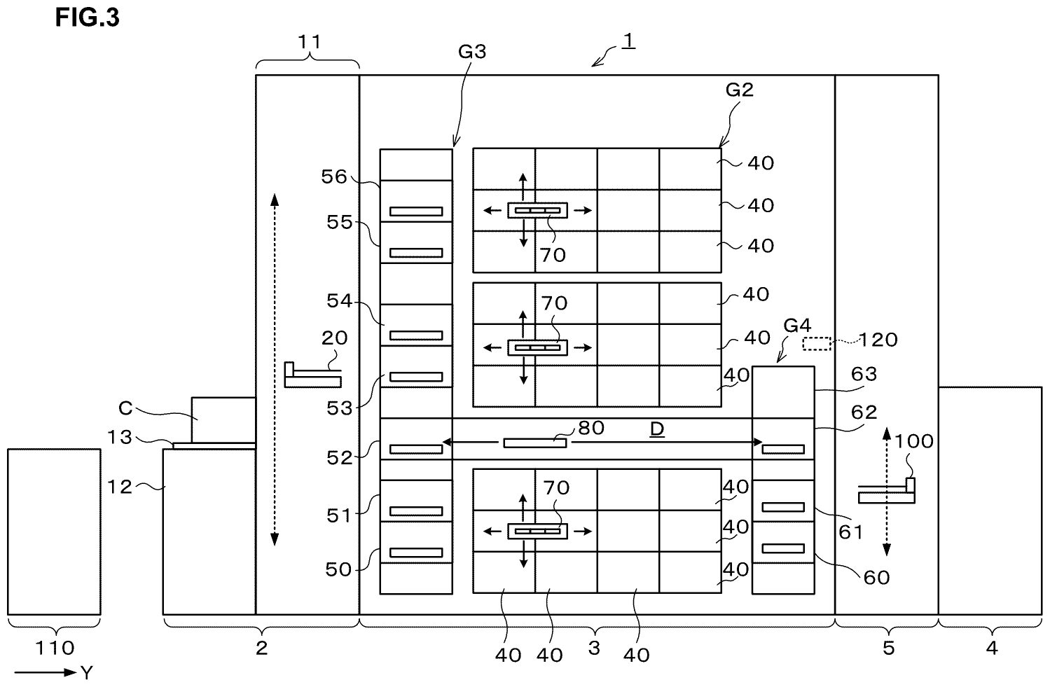

FIG. 1 is an explanatory view illustrating the outline of a configuration of a semiconductor manufacturing system according to an embodiment. FIG. 2 and FIG. 3 are explanatory views illustrating the outline of the configuration on the front side and the rear side of a coating and developing treatment apparatus 1 as a semiconductor manufacturing apparatus included in the semiconductor manufacturing system in FIG. 1, respectively.

A semiconductor manufacturing system 500 in FIG. 1 includes the coating and developing treatment apparatus 1, an operation terminal 201, and a control device 301.

The coating and developing treatment apparatus 1 has a plurality of modules. Specifically, the coating and developing treatment apparatus 1 has, as illustrated in FIG. 1 to FIG. 3, a cassette station 2 including a later-explained transfer module 20 and so on into/out of which a cassette C being a container capable of housing a plurality of wafers W as substrates is transferred, and a treatment station 3 including a plurality of various treatment modules which perform the predetermined treatments such as the resist coating treatment. The coating and developing treatment apparatus 1 further has a configuration in which the cassette station 2, the treatment station 3, and an interface station 5 which delivers the wafer W to/from an exposure apparatus 4 adjacent to the treatment station 3 are integrally connected.

The cassette station 2 is divided into, for example, a cassette transfer-in/out section 10 and a wafer transfer section 11. The cassette transfer-in/out section 10 is provided, for example, at an end on a Y-direction negative direction side in the coating and developing treatment apparatus 1. In the cassette transfer-in/out section 10, a cassette stage 12 is provided. On the cassette stage 12, a plurality of, for example, four stage plates 13 are provided. The stage plates 13 are provided side by side in a row in an X-direction (an up-down direction in FIG. 1) being a horizontal direction. On the stage plates 13, cassettes C can be mounted when the cassettes C are transferred to/from the outside of the coating and developing treatment apparatus 1.

In the wafer transfer section 11, the transfer module 20 is provided which transfers the wafer. The transfer module 20 is configured to be movable on a transfer path 21 extending in the X-direction. The transfer module 20 is movable also in the up-down direction and around a vertical axis (in a θ-direction), and can transfer the wafer between the cassette C on each of the stage plates 13 and a later-explained delivery module in a third block G3 in the treatment station 3.

In the treatment station 3, a plurality of, for example, first to fourth four blocks G1, G2, G3, G4 each including various modules are provided. For example, the first block G1 is provided on the front side (an X-direction negative direction side in FIG. 1) in the treatment station 3, and the second block G2 is provided on the rear side (an X-direction positive direction side in FIG. 1) in the treatment station 3. Further, the third block G3 is provided on the cassette station 2 side (a Y-direction negative direction side in FIG. 1) in the treatment station 3, and the fourth block G4 is provided on the interface station 5 side (a Y-direction positive direction side in FIG. 1) in the treatment station 3.

In the first block G1, as illustrated in FIG. 2, a plurality of solution treatment modules, for example, a developing treatment module 30 and a resist coating module 31 are arranged in this order from the bottom. Further, the developing treatment module 30 and the resist coating module 31 are provided, for example, three each arranged side by side in the horizontal direction. Note that the numbers and the arrangements of the developing treatment modules 30 and the resist coating modules 31 can be arbitrarily selected.

The developing treatment module 30 performs a developing treatment on the wafer W. Specifically, the developing treatment module 30 performs the developing treatment on a resist film on the wafer W subjected to a PEB treatment. The resist coating module 31 applies a resist on the wafer W to form a resist film.

In each of the developing treatment module 30 and the resist coating module 31, a predetermined treatment solution is applied onto the wafer W, for example, by the spin coating method. In the spin coating method, the treatment solution is discharged onto the wafer W, for example, from a discharge nozzle and the wafer W is rotated to diffuse the treatment solution over the surface of the wafer W.

In the second block G2, as illustrated in FIG. 3, thermal treatment modules 40 each of which performs thermal treatments such as heating and cooling of the wafer W are provided to line up in the up-down direction and the horizontal direction. Note that the number and the arrangement of the thermal treatment modules 40 can be arbitrarily selected.

The thermal treatment modules 40 perform a PAB treatment, a PEB treatment, a post-baking treatment for heat-treating the wafer W after the developing treatment, and so on.

In the third block G3, a plurality of delivery modules 50, 51, 52, 53, 54, 55, 56 are provided in order from the bottom. In the third block G3, an ionizer (not illustrated) may be provided. The ionizer is a module which performs destaticization processing on the wafer W. The destaticization processing by the ionizer is performed before the treatment in the treatment station 3, and after the treatment in the treatment station 3 and before return to the cassette C, namely, return to the cassette C for transfer to another semiconductor manufacturing apparatus.

Further, in the fourth block G4, a plurality of delivery modules 60, 61, 62, 63 are provided in order form the bottom.

As illustrated in FIG. 1, in a region surrounded by the first block G1 to the fourth block G4, a wafer transfer region D is formed. In the wafer transfer region D, for example, a transfer module 70 which transfers the wafer W is arranged.

The transfer module 70 has a transfer arm 70a movable, for example, in the Y-direction, the θ-direction, and the up-down direction. The transfer module 70 can move the transfer arm 70a holding the wafer W in the wafer transfer region D and transfer the wafer W to predetermined modules in the first block G1, the second block G2, the third block G3, and the fourth block G4 therearound. A plurality of the wafer transfer modules 70 are arranged one above the other, for example, as illustrated in FIG. 3, each of which can transfer the wafer W, for example, to a predetermined module at a similar height in the blocks G1 to G4.

Further, in the wafer transfer region D, a shuttle transfer module 80 is provided which linearly transfers the wafer between the third block G3 and the fourth block G4.

The shuttle transfer module 80 can linearly move the wafer W supported thereon in the Y-direction and transfer the wafer W between the delivery module 52 in the third block G3 and the delivery module 62 in the fourth block G4 at similar heights.

As illustrated in FIG. 1, a transfer module 90 is provided on the X-direction positive direction side of the third block G3. The transfer module 90 has a transfer arm 90a movable, for example, in the X-direction, the θ-direction, and the up-down direction. The transfer module 90 can move the transfer arm 90a holding the wafer W up and down to transfer the wafer W to each of the delivery modules 50 to 56 in the third block G3.

In the interface station 5, a transfer module 100 and a delivery module 101 are provided. The transfer module 100 has a transfer arm 100a movable, for example, in the θ-direction and the up-down direction. The transfer module 100 can transfer the wafer W to/from each of the delivery modules 60 to 63 in the fourth block G4 and the exposure apparatus 4, while holding the wafer W by the transfer arm 100a.

Further, the coating and developing treatment apparatus 1 has a cabinet 110.

The cabinet 110 houses bottles (not illustrated) as solution storages for storing treatment solutions to be supplied, for example, to the solution treatment modules such as the resist coating module 31. Further, the cabinet 110 stores some of solution supply modules which supply the treatment solutions in the bottles to the corresponding solution treatment modules.

The cabinet 110 is installed in a manner to be arranged in an apparatus width direction (Y-direction in FIG. 1 and so on), for example, in the order of the cabinet 110, the cassette station 2, the treatment station 3, and the interface station 5. Further, the cassette station 2, the treatment station 3, and the interface station 5 may be installed on a floor and the cabinet 110 may be installed under the floor.

The coating and developing treatment apparatus 1 has a plurality of terminal connection ports 120 to which the operation terminal 201 is to be connected. To each of the terminal connection ports 120, the operation

terminal 201 can be connected via a LAN cable 202. The number of the operation terminals 201 connected to the plurality of terminal connection ports 120 of the coating and developing treatment apparatus 1 is, for example, one.

The terminal connection ports 120 are provided, for example, on the front side of the treatment station 3, the rear side of the treatment station 3, and the front side of the cabinet 110. The terminal connection ports 120 are connected to ports (not illustrated) of a later-explained intelligent hub 401, respectively. Specifically, the terminal connection port 120 is connected to a port corresponding to the terminal connection port 120 in the coating and developing treatment apparatus 1 via a LAN cable (not illustrated). Note that the port connected to the terminal connection port 120 on the front side of the treatment station 3 may be called a front side port, the port connected to the terminal connection port 120 on the rear side of the treatment station may be called a rear side port, and the port connected to the terminal connection port 120 on the front side of the cabinet 110 may be called a cabinet port in some cases in the following.

Though not illustrated, the terminal connection port 120 may further be provided on the lateral side of the cassette station 2. The terminal connection port 120 provided on the lateral side of the cassette station 2 is connected to, for example, a later-explained dedicated port via a LAN cable (not illustrated).

Note that the terminal connection ports 120 may be covered with covers (not illustrated) so as not to be exposed.

Further, in this embodiment, the terminal connection ports 120 also serve as detectors for detecting the operation terminal 201 connected to the terminal connection ports 120.

As illustrated in FIG. 1, the operation terminal 201 is, for example, an operation terminal such as a tablet terminal, and has a controller 211, a display 212, and an inputter 213.

The controller 211 is a computer including, for example, a processor such as a CPU, a memory, and so on, and has a program storage (not illustrated). The program storage stores a program including a command for causing the display 212 to display an operation screen of the coating and developing treatment apparatus 1 and for controlling the coating and developing treatment apparatus 1 based on the operation of a user, namely, an operator on the operation screen. Note that the above program may be the one recorded in a computer-readable storage medium H and installed from the storage medium H into the controller 211. The storage medium H may be a transitory one or a non-transitory one. Part of all of the program may be realized by dedicated hardware (circuit board). Besides, the above program may be the one downloaded from the control device 301.

The display 212 displays a screen such as the operation screen of the coating and developing treatment apparatus 1, and is composed of, for example, a liquid crystal display, an organic EL display, or the like.

The inputter 213 accepts the input, namely, the operation of the user, and includes, for example, a touch panel integrated with the display 212.

The operation terminal 201 having the above components is connected to the terminal connection port 120 via the LAN cable 202. The user's operation on the operation terminal 201 may be performed only when the operation terminal 201 is located within 1 to 4 m (namely, within a visible range) from the coating and developing treatment apparatus 1.

The control device 301 is a computer including, for example, a processor such as a CPU, a memory, and so on, and has a storage 301a and a controller 301b.

The storage 301a stores various information, and has a memory such as a RAM and a storage device such as an HDD. The storage 301a stores a program including a command for controlling the operations of the above various modules and the various transfer modules of the coating and developing treatment apparatus 1. Further, the program storage stores a program for controlling the coating and developing treatment apparatus 1 (specifically, the operations of the above various modules and the various transfer modules) based on the operation from the user on the operation terminal 201. Note that those programs may be the ones recorded in a computer-readable storage medium M and installed from the storage medium M into the controller 301b. The storage medium M may be a transitory one or a non-transitory one. Part of all of the programs may be realized by dedicated hardware (circuit board).

In this embodiment, the semiconductor manufacturing system 500 further includes the intelligent hub 401 as a relay device.

The intelligent hub 401 connects the operation terminal 201 connected to the terminal connection port 120 and the control device 301 in a communicable manner. The intelligent hub 401 has ports (not illustrated) as relay connection ports. The port is connected to the terminal connection port 120 via the LAN cable in a manner that the operation terminal 201 connected to the terminal connection port 120 and the intelligent hub 401 can communicate with each other. In one embodiment, the ports included in the intelligent hub 401 include a dedicated port as a dedicated relay connection port. The dedicated port is used in performing control about a specific control item of control items of the coating and developing treatment apparatus 1.

When forwarding a later-explained screen information transmission request from the operation terminal 201 to the control device 301, the intelligent hub 401 transmits also identification information on a port to which the operation terminal 201 that is the transmission source of the screen information transmission request is connected, to the control device 301.

### <Controller 211 of the Operation Terminal 201>

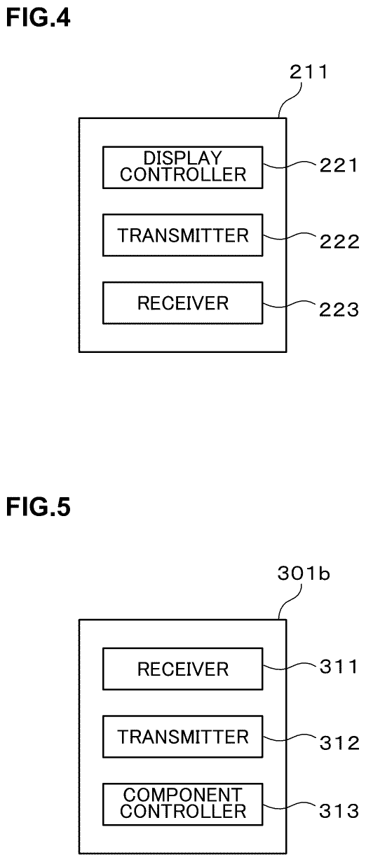

FIG. 4 is a functional block diagram of the controller 211 of the operation terminal 201.

The controller 211 has, as illustrated in FIG. 4, a display controller 221, a transmitter 222, and a receiver 223 which are realized by the processor such as CPU reading and executing the program stored in the program storage (not illustrated).

The display controller 221 causes the display 212 to display various screens. The screens displayed on the display 212 by the display controller 221 include the operation screen of the coating and developing treatment apparatus 1 based on the screen information received from the control device 301. The screen information is information related to the operation screen of the coating and developing treatment apparatus 1.

The transmitter 222 transmits the various information to the control device 301. Specifically, the information to be transmitted from the transmitter 222 to the control device 301 includes the screen information transmission request requesting transmission of the screen information and operational information based on the operation of the user on the operation screen of the coating and developing treatment apparatus 1.

The receiver 223 receives the various information from the control device 301. Specifically, the receiver 223 receives the screen information from the control device 301.

### <Controller 301b of the Control Device 301>

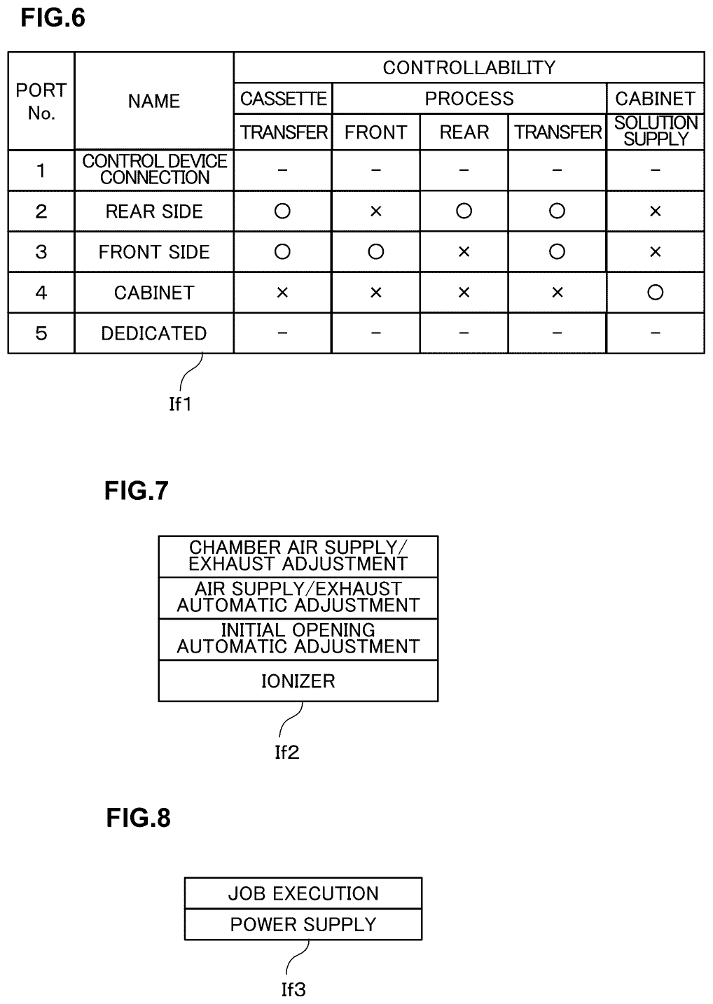

FIG. 5 is a functional block diagram of the controller 301b of the control device 301. FIG. 6 is a chart illustrating an example of module restriction information. FIG. 7 is a chart illustrating an example of item restriction information. FIG. 8 is a chart illustrating an example of specific item information.

As illustrated in FIG. 5, the controller 301b of the control device 301 has a receiver 311, a transmitter 312, and a component controller 313 which are realized by the processor such as CPU reading and executing the program stored in the storage 301a.

Further, in the control device 301, the storage 301a stores the various information as explained above. The information stored in the storage 301a includes the module restriction information. The module restriction information indicates modules included in the coating and developing treatment apparatus 1, which are controllable modules corresponding to the terminal connection ports 120, in units of a detector, namely, in units of the terminal connection port 120. Specifically, as illustrated in FIG. 6, module restriction information IF1 indicates controllable modules corresponding to the ports of the intelligent hub 401 to which the terminal connection ports 120 are connected, for each port. The module restriction information may indicate the controllable modules by a module group to which the modules belong.

The module restriction information IF1 in FIG. 6 indicates the following as the controllable modules corresponding to the rear side port.
“Transfer” of “cassette”, namely, the transfer module 20 in the cassette station 2
“Rear” of “process”, namely, the module group on the rear side in the treatment station 3
“Transfer” of “process”, namely, the transfer module group in the treatment station 3

The module group on the rear side includes, for example, the thermal treatment module 40.

Further, the module restriction information IF1 in FIG. 6 indicates the following as the controllable modules corresponding to the front side port.
“Transfer” of “cassette”, namely, the transfer module 20 in the cassette station 2
“Front” of “process”, namely, the module group on the front side in the treatment station 3
“Transfer” of “process”, namely, the transfer module group in the treatment station 3

The module group on the front side includes, for example, the developing treatment module 30, the resist coating module 31, and so on.

Further, the module restriction information IF1 in FIG. 6 indicates “solution supply” of “cabinet”, namely, (some of) the solution treatment modules in the cabinet 110, as the controllable modules corresponding to the cabinet port.

Further, the information stored in the storage 301a may include the item restriction information. The item restriction information indicates controllable items corresponding to the authority of the user among the control items relating to the modules included in the coating and developing treatment apparatus 1, for each authority of the user. For example, as illustrated in FIG. 7, item restriction information IF2 indicates items which are not controllable by a user having an authority of a general user but are controllable only by a user having an authority of an operator, namely, a field engineer, among control items relating to the modules included in the coating and developing treatment apparatus 1. The item restriction information IF2 in FIG. 7 indicates the following as items controllable by the user having the authority of the operator.
“Chamber air supply/exhaust adjustment”, namely, an item of manually adjusting an air supply rate and an air exhaust rate to/from the chamber included in the corresponding module
“Air supply/exhaust automatic adjustment”, namely, an item of automatically adjusting an air exhaust rate so that the inside of the chamber of the corresponding module becomes a specified pressure
“Initial opening automatic adjustment”, namely, an item of automatically adjusting the opening of a flow rate regulating valve included in the solution supply module for each supply flow rate region of the treatment solution
“Ionizer”, namely, an item of adjusting the ion concentration at the destaticization in the chamber included in the ionizer at the destaticization of the wafer W by the ionizer

Further, the information stored in the storage 301a may include the specific item information. The specific item information indicates specific items being items controllable only by using the operation terminal 201 connected to the dedicated port of the intelligent hub 401 via the terminal connection port 120, among the control items of the coating and developing treatment apparatus 1. Specific item information 13 in FIG. 8 indicates the following as the specific items.
“Job execution”, namely, an item for which the coating and developing treatment apparatus 1 is made to execute a job
“Power supply”, namely, an item of turning ON/OFF the power supply (not illustrated) of the coating and developing treatment apparatus 1

The receiver 311 receives the various information from the operation terminal 201. The information received by the receiver 311 from the operation terminal 201 includes the above screen information transmission request and the operational information. Specifically, the receiver 311 receives the various information from the operation terminal 201 via the intelligent hub 401. At least the screen information transmission request of the information received by the receiver 311 from the operation terminal 201 via the intelligent hub 401 includes information on the port of the intelligent hub 401 to which the operation terminal 201 that is the transmission source of the information is connected via the terminal connection port 120.

The transmitter 312 transmits the various information to the operation terminal 201. The information transmitted by the transmitter 312 to the operation terminal 201 includes the screen information based on the module restriction information. The screen information is transmitted to the operation terminal 201 that is the transmission source of the screen information transmission request according to the request.

In the case where the operation terminal 201 is connected to one of the terminal connection ports 120 and the operation terminal 201 is detected via the corresponding detector, the transmitter 312 transmits the screen information including the information indicating the controllable modules corresponding to the detector used for the detection, to the connected operation terminal 201, based on the module restriction information.

In the form in which the terminal connection ports 120 also serve as the detectors as in this embodiment, in the case where the operation terminal 201 is connected to one of the terminal connection ports 120, the transmitter 312 transmits the following screen information to the connected operation terminal 201, based on the module restriction information. More specifically, the transmitter 312 transmits the screen information including the information indicating the controllable modules corresponding to the terminal connection port 120 to which the operation terminal 201 is connected, to the connected operation terminal 201. Specifically, the transmitter 312 transmits the screen information including the information on the controllable modules corresponding to the port of the intelligent hub 401 to which the operation terminal 201 is connected via the terminal connection port 120 to the connected operation terminal 201, based on the module restriction information.

The component controller 313 controls the components (including the modules) of the coating and developing treatment apparatus 1 and adjusts the settings of the treatment conditions and the like base on the operational information received by the receiver 311. More specifically, the component controller 313 performs maintenance and the like of the components (including the modules) of the coating and developing treatment apparatus 1 based on the operational information received by the receiver 311.

### <Example of a Display Flow>

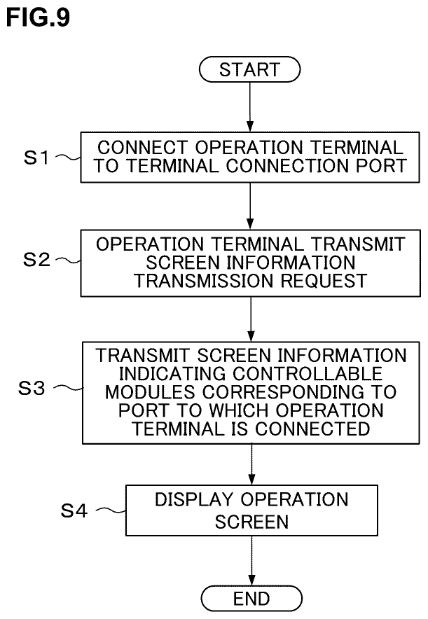

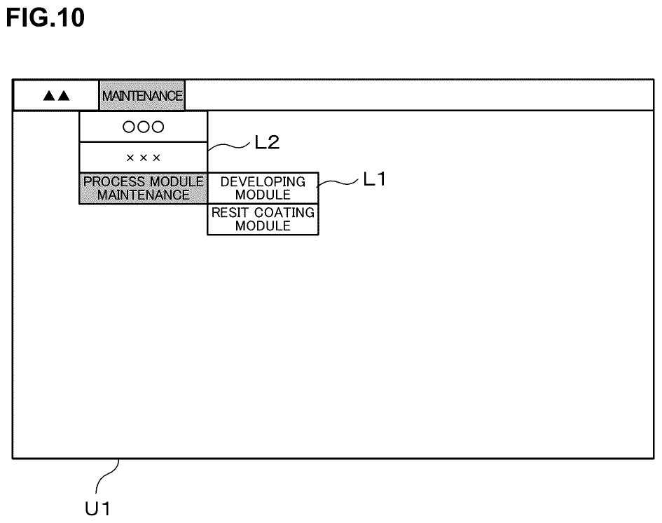

FIG. 9 is a flowchart for explaining an example of a flow when the operation screen is displayed on the display 212 of the operation terminal 201. FIG. 10 is a chart illustrating an example of the operation screen.

When the operation screen is displayed on the display 212 of the operation terminal 201, as illustrated in FIG. 9, after the operation terminal 201 is connected to the terminal connection port 120 (after Step S1), the transmitter 222 of the operation terminal 201 transmits the screen information transmission request to the control device 301 (Step S2).

Specifically, the transmitter 222 of the operation terminal 201 transmits the screen information transmission request to the control device 301 via the intelligent hub 401. In this event, the intelligent hub 401 includes the information on the port of the intelligent hub 401 to which the operation terminal 201 that is the transmission source of the screen information transmission request is connected via the terminal connection port 120, in the screen information transmission request relayed from the operation terminal 201 to the control device 301.

Upon receipt of the screen information transmission request by the receiver 311 of the control device 301, the transmitter 312 transmits the following screen information to the operation terminal 201 that is the transmission source of the screen information transmission request, based on the module restriction information (Step S3). Specifically, upon receipt of the screen information transmission request by the receiver 311 of the control device 301, the transmitter 312 transmits the screen information including the following information via the intelligent hub 401 based on the module restriction information. More specifically, the screen information to be transmitted in this event includes information on the controllable modules indicated by the module restriction information which is information indicating the controllable modules corresponding to the port of the intelligent hub 401 to which the operation terminal 201 that is the transmission source of the screen information transmission request is connected via the terminal connection port 120.

Upon receipt of the screen information by the receiver 223 of the operation terminal 201 that is the transmission source of the screen information transmission request, the display 212 displays the operation screen based on the screen information under the control of the display controller 221 (Step S4).

As illustrated in FIG. 10, a list L1 of the controllable modules is displayed on an operation screen U1 displayed thereby, for example, according to the operation of the user on the operation screen U1. In the list L1, only the controllable modules corresponding to the port of the intelligent hub 401 to which the operation terminal 201 is connected via the terminal connection port 120, which are indicated in the module restriction information, are displayed. In the operation screen U1, a list L2 of control items of the modules may be displayed. When the user selects one control item included in the list L2 of the control items of the modules, the list L1 of the controllable modules may be displayed. In this case, in the list L1 of the controllable modules, only the modules corresponding to the control item selected by the user among the controllable modules corresponding to the port of the intelligent hub 401 to which the operation terminal 201 is connected via the terminal connection port 120 which are indicated in the module restriction information, may be displayed. Further, the list L2 of the control items of the modules may be displayed when the user selects a specific menu (for example, “maintenance” menu) displayed on the operation screen U1.

The operation screen U1 in FIG. 10 is a screen displayed in the case where the operation terminal 201 is connected to the front side port of the intelligent hub 401 via the terminal connection port 120. In the list L1, controllable modules corresponding to the front side port and equivalent to treatment modules corresponding to the control item of “process module maintenance” selected by the user are displayed in a tree form. Note that a list of the developing treatment modules 30 included in the coating and developing treatment apparatus 1 may be displayed when the user selects, for example, the “developing module” in the list L1 of the controllable modules.

### <Main Operations and Effects of the Embodiment>

As explained above, in this embodiment, in the case where the operation terminal 201 is connected to the terminal connection port 120 and the screen information transmission request is transmitted from the operation terminal 201, the transmitter 312 of the control device 301 transmits the following screen information to the operation terminal 201 that is the transmission source of the request. The screen information to be transmitted by the transmitter 312 to the operation terminal 201 that is the transmission source of the screen information transmission request includes the information indicating the controllable modules indicated in the module restriction information, namely, the controllable modules registered in advance, which are the modules corresponding to the terminal connection port 120 to which the operation terminal 201 is connected. Specifically, the screen information to be transmitted by the transmitter 312 to the operation terminal 201 that is the transmission source of the screen information transmission request includes the information on the controllable modules indicated in the module restriction information, namely, registered in advance, which are the controllable modules corresponding to the port of the intelligent hub 401 to which the operation terminal 201 is connected via the terminal connection port 120.

Therefore, in the operation screen displayed based on the received screen information by the operation terminal 201 that is the transmission source of the screen information transmission request, the controllable modules indicated in the module restriction information, namely, registered in advance, which are the modules corresponding to the terminal connection port 120 to which the operation terminal 201 is connected are indicated. Specifically, the controllable modules indicated in the module restriction information, namely, registered in advance, which are the controllable modules corresponding to the port of the intelligent hub 401 to which the operation terminal 201 is connected via the terminal connection port 120 are indicated.

Accordingly, by registering appropriate modules according to the positions of the terminal connection ports 120 in advance in units of the terminal connection port 120 in the module restriction information, specifically, by registering appropriate modules according to the positions of the terminal connection ports 120 connected to the ports in advance for each port, for example, the following can be suppressed. Specifically, when the user, namely, the operator controls the module in the coating and developing treatment apparatus 1 via the operation terminal 201 connected to the terminal connection port 120, it is possible to prevent danger on another operator at a position not visible from the former operator. The above “appropriate modules according to the positions of the terminal connection ports 120” are, for example, modules in a visual field of the user who operates the operation terminal 201 connected to the terminal connection port 120 via the LAN cable 202.

### <Another Example of the Display Flow>

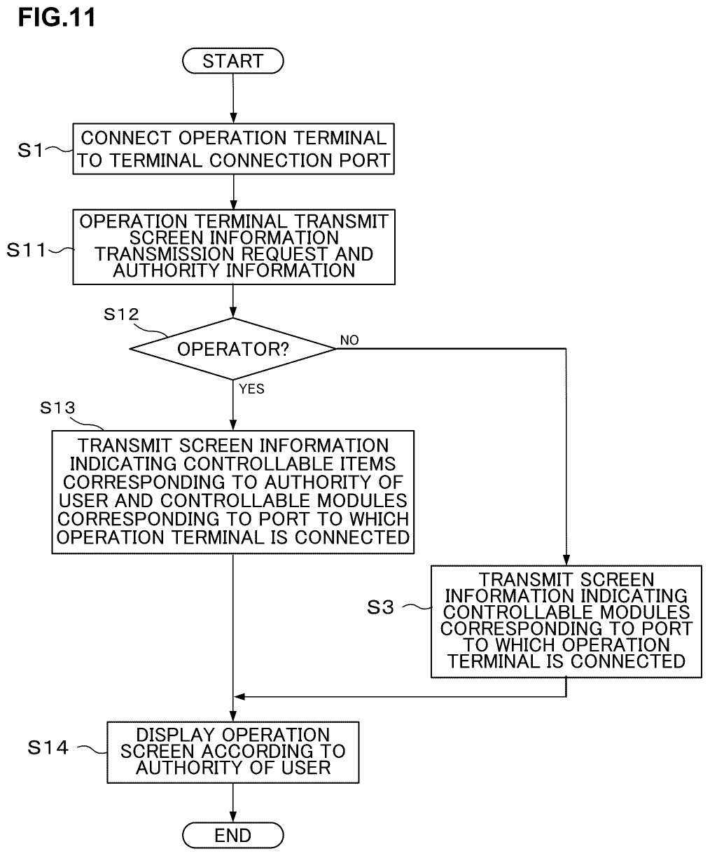

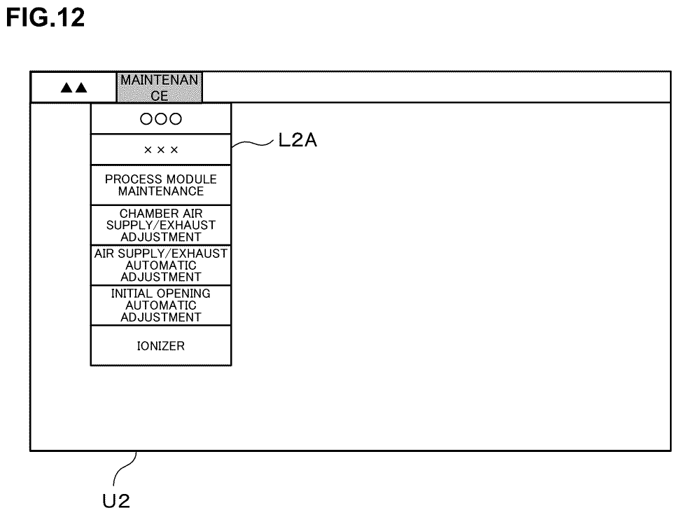

FIG. 11 is a flowchart for explaining another example of the flow when the operation screen is displayed on the display 212 of the operation terminal 201. FIG. 12 is a chart illustrating an example of the operation screen.

As illustrated in FIG. 11, after the operation terminal 201 is connected to the terminal connection port 120 (after Step S1), the transmitter 222 of the operation terminal 201 may also transmit information on the authority of the user of the operation terminal 201 (for example, log-in information) in addition to the screen information transmission request to the control device 301 (Step S11).

Note that the information on the authority of the user of the operation terminal 201 may be included in the screen information transmission request, or the transmitter 222 of the operation terminal 201 may transmit the information on the authority before or after the screen information transmission request.

Upon receipt, namely, acquisition of the screen information transmission request and the information on the authority of the user by the receiver 311 of the control device 301, the transmitter 312 transmits the screen information including the information indicating the controllable items corresponding to the authority of the user to the operation terminal 201 that is the transmission source of the screen information transmission request, based on an acquisition result of the information on the authority of the user and the item restriction information.

Specifically, first, it is determined whether the authority of the user is an operator, based on the information on the authority of the user acquired by the controller 301b (Step S12).

In the case of the operator (in the case of YES), the transmitter 312 transmits screen information including the information indicating the controllable items corresponding to the authority of the operator and information indicating the above controllable modules to the operation terminal 201 that is the transmission source of the screen information transmission request, based on the item restriction information (Step S13).

In the case of not the operator (in the case of NO), the above Step S3 is performed.

Thereafter, upon receipt of the screen information by the receiver 223 of the operation terminal 201 that is the transmission source of the screen information transmission request, the display 212 displays the operation screen according to the authority of the user based on the screen information under the control of the display controller 221 (Step S14).

In the case where the authority of the user is a general user, for example, the above operation screen U1 in FIG. 10 is displayed.

On the other hand, in the case where the authority of the user is an operator, for example, an operation screen U2 in FIG. 12 is displayed. A list L2A of the controllable items of the modules in the operation screen U2 includes controllable items (“chamber automatic air supply/exhaust adjustment” and so on) corresponding to the authority of the operator.

This makes it possible to appropriately display the controllable items according to the authority of the user.

<Processing in the Case of being Connected to the Dedicated Port>

Also in the case where the operation terminal 201 is connected to the dedicated port via the terminal connection port 120, the operation terminal 201 transmits the screen information transmission request to the control device 301.

In the control device 301, the transmitter 312 transmits other screen information indicating specific items being items controllable only by using the operation terminal connected to the dedicated port via the terminal connection port 120, to the operation terminal 201 that is the transmission source of the screen information transmission request, based on the above specific item restriction information.

The operation terminal 201 connected to the dedicated port then displays the operation screen based on the above other screen information. Specifically, the display 212 of the operation terminal 201 displays the operation screen based on the above other screen information under the control of the display controller 221.

### <Another Example of the Connection Form of the Operation Terminal 201>

A plurality of the operation terminals 201 are not connected at the same time to the terminal connection ports 120 of the coating and developing treatment apparatus 1 in the above example, but may be connected.

In the case where they are connected at the same time, when the transmitter 312 of the control device 301 transmits the screen information based on the module restriction information to the operation terminal 201 connected later, the following may be performed. More specifically, the module controlled via the operation terminal 201 connected first may be excluded from the information on the controllable modules included in the screen information based on the module restriction information.

Besides, in the case where they are connected at the same time, instead of the above, the component controller 313 may disable, that is, may ignore the operation on the operation terminal 201 connected later, related to the module controlled via the operation terminal 201 connected first.

### <Another Example of the Installation Position of the Terminal Connection Port 120>

The terminal connection port 120 is not provided in the interface station 5 in the above example, but may be provided. In this case, the terminal connection port 120 may be provided on both the front side and the rear side of the interface station 5.

Further, the terminal connection port 120 may be provided at each of a plurality of locations different in position in the height direction in equivalent regions in the apparatus width direction on the front side and the rear side of the coating and developing treatment apparatus 1.

The treatment station 3 is divided into a plurality of blocks in the apparatus width direction in the coating and developing treatment apparatus 1 in some cases. In this case, the terminal connection port 120 may be provided for each block such as on the front side and the rear side in each block so as not to generate a range of a blind spot of the user of the operation terminal 201 connected to the terminal connection port 120.

### <Another Example of the Semiconductor Manufacturing Apparatus>

In the above example, the coating and developing treatment apparatus 1 is used as the semiconductor manufacturing apparatus. Instead of this, a cleaning apparatus may be used as the semiconductor manufacturing apparatus.

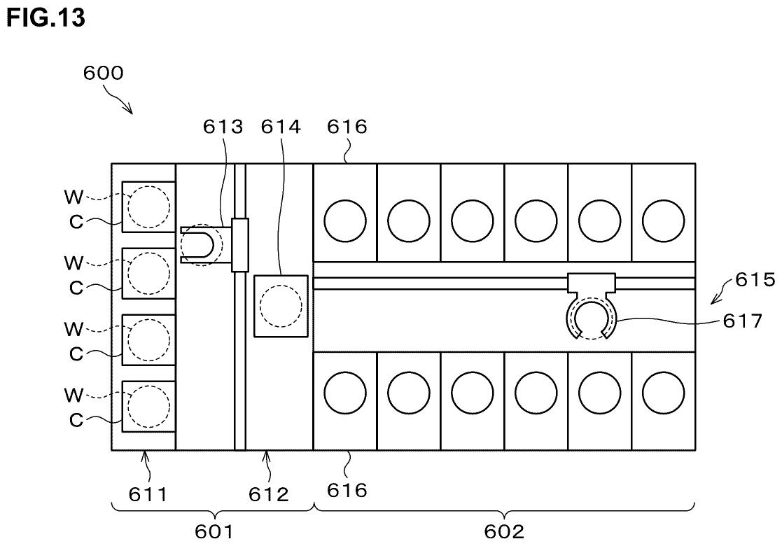

FIG. 13 is an explanatory view illustrating the outline of an internal configuration of a cleaning apparatus 600 as the semiconductor manufacturing apparatus. As illustrated in FIG. 13, the cleaning apparatus 600 includes a transfer-in/out station 601 and a treatment station 602. The transfer-in/out station 601 and the treatment station 602 are adjacently provided.

The transfer-in/out station 601 includes a cassette mounting section 611 and a transfer section 612. On the cassette mounting section 611, a plurality of cassettes C each housing a plurality of wafers W are mounted.

The transfer section 612 is provided adjacent to the cassette mounting section 611 and includes a transfer module 613 and a deliverer 614 therein. The transfer module 613 includes a wafer holding mechanism which holds the wafer W. Further, the transfer module 613 can move in the horizontal direction and the vertical direction and turn around the vertical axis, and transfers the wafer W between the cassette C and the deliverer 614 using the wafer holding mechanism.

The treatment station 602 is provided adjacent to the transfer section 612. The treatment station 602 includes a transfer section 615 and a plurality of cleaning modules 616. The plurality of cleaning modules 616 are provided side by side on both sides of the transfer section 615.

The transfer section 615 includes a transfer module 617 therein. The transfer module 617 includes a wafer holding mechanism which holds the wafer W. Further, the transfer module 617 can move in the horizontal direction and the vertical direction and turn around the vertical axis, and transfers the wafer W between the deliverer 614 and the cleaning module 616 using the wafer holding mechanism.

The cleaning module 616 performs a cleaning treatment on the wafer W transferred by the transfer module 617.

In the case of using the cleaning apparatus 600 as the semiconductor manufacturing apparatus, the terminal connection port is provided on both the front side and the rear side in the treatment station 602 though not illustrated.

### Modification Example

The information indicated in the module restriction information, namely, the registered information may differ depending on the installation position of the cabinet 110 at which the terminal connection port 120 is provided. For example, in the case where the cabinet 110 is installed on the floor, the transfer module such as the transfer module 70 is registered in the module restriction information as the adjustable module corresponding to the terminal connection port 120, but in the case where the cabinet 110 is installed under the floor, the transfer module may not be registered in the module restriction information as the adjustable module.

The module restriction information IF1 may include the following read-only module information. The read-only module information indicates the modules included in the coating and developing treatment apparatus 1, which are the modules which cannot be controlled but whose setting conditions corresponding to the terminal connection port 120 can be confirmed, namely, browsed, in units of the detector, namely, in units of the terminal connection port 120. Specifically, the read-only module information indicates, for each port, the modules whose setting conditions corresponding to the port of the intelligent hub 401 to which the operation terminal 201 is connected (hereinafter, referred to as read-only modules) can be browsed only. Then, for example, in the case where the operation terminal 201 is connected to one of the terminal connection ports 120, the transmitter 312 may transmit the screen information including the information indicating the read-only module corresponding to the terminal connection port 120 to which the operation terminal 201 is connected, to the connected operation terminal 201 based on the read-only module information. Specifically, the transmitter 312 may transmit the screen information including the information indicating the read-only module corresponding to the port of the intelligent hub 401 to which the operation terminal 201 is connected via the terminal connection port 120, to the connected operation terminal 201. In addition, the connected operation terminal 201 may be made to be able to display not only the controllable module corresponding to the terminal connection port 120 to which the operation terminal 201 is connected but also the read-only module corresponding to the terminal connection port 120 (specifically, corresponding to the above port).

Thus, for example, in the case where the operation terminal 201 is connected to the terminal connection port 120 for the front side port, the following is possible. Specifically, for the modules maintenable via the operation terminal 201, it is possible to limit, in terms of safety, the modules maintenable via the operation terminal 201 to the treatment modules on the front side in the treatment station 3 and the transfer modules while enabling confirmation only of the setting conditions for the treatment modules on the rear side in the treatment station 3 via the operation terminal 201. Accordingly, is it possible to perform operation on the controllable module while confirming the setting conditions of uncontrollable modules, via the operation terminal 201.

The terminal connection ports 120 also serve as the detectors for detecting the operation terminal 201 connected to the terminal connection ports 120. Instead of this, the detector may be provided around the terminal connection port 120, separately from the terminal connection port 120. The detector may be, for example, an RFID reader. Further, the detector may be detecting radio from the operation terminal 201, in which case it may detect the operation terminal connected to the terminal connection port 120 with the intensity of the detected radio. Further, a terminal connection port for serial communication may be provided as the detector, around the terminal connection port 120 separately from the terminal connection port 120 for LAN.

Note that in any case, the controllable modules corresponding to the detectors are indicated in units of the detector in the module restriction information.

The embodiments disclosed herein are examples in all respects and should not be considered to be restrictive. Various omissions, substitutions, and changes may be made in the embodiments without departing from the scope and spirit of the attached claims. For example, configuration requirements of the above embodiments can be arbitrarily combined. The operations and effects about the configuration requirements relating to a combination can be obtained as a matter of course from an arbitrary combination, and those skilled in the art can obtain obvious other operations and other effects from the description herein.

Further, the effects described herein are merely explanatory or illustrative in all respects and not restrictive. The technique relating to this disclosure can offer obvious other clear effects to those skilled in the art from the description herein in addition to or instead of the above effects.

Note that the following configuration examples also belong to the technical scope of this disclosure.
(1) A control device for controlling a semiconductor manufacturing apparatus having a plurality of modules, the device for controlling the semiconductor manufacturing apparatus based on an operation from a user on an operation terminal displaying an operation screen of the semiconductor manufacturing apparatus,
   the semiconductor manufacturing apparatus including:
      a plurality of terminal connection ports to which the operation terminal is to be connected; and
      a plurality of detectors for detecting the operation terminal connected to the terminal connection ports, the terminal connection ports also serving as the detectors or the detectors being provided around the terminal connection ports,
   the control device being configured to:
   store module restriction information, the module restriction information indicating controllable modules corresponding to the detectors in units of the detector; and
   in a case of the operation terminal being connected to one of the terminal connection ports and the operation terminal being detected via the corresponding detector, transmit screen information about the operation screen to the connected operation terminal based on the module restriction information, the screen information including information indicating the controllable modules corresponding to the detector used for the detection.
(2) The control device according to the (1), wherein:
   the terminal connection ports also serve as the detectors;
   the controllable modules corresponding to the terminal connection ports are recorded in units of the terminal connection port in the module restriction information; and
   in the case where the operation terminal is connected to one of the terminal connection ports, the screen information including information indicating the controllable modules corresponding to the terminal connection port to which the operation terminal is connected is transmitted to the connected operation terminal, based on the module restriction information.
(3) The control device according to the (2), wherein:
   the control device is connected to the operation terminal connected to the terminal connection port via a relay device;
   the relay device has a plurality of relay connection ports to be connected to the terminal connection ports;
   the module restriction information indicates controllable modules corresponding to the relay connection ports for each of the relay connection ports; and
   in the case where the operation terminal is connected to one of the terminal connection ports, the screen information including the information indicating the controllable modules corresponding to the relay connection port to which operation terminal is connected via the terminal connection port is transmitted to the connected operation terminal via the relay device, based on the module restriction information.
(4) The control device according to any one of the (1) to (3), wherein:
   the control device stores item restriction information, the item restriction information indicating controllable items corresponding to an authority of the user among control items of the modules for each authority of the user; and
   in the case where the operation terminal is connected to one of the terminal connection ports and the operation terminal is detected via the corresponding detector, the screen information including information indicating the controllable items corresponding to the authority of the user is transmitted to the connected operation terminal, based on an acquisition result of the information on the authority of the user using the connected operation terminal and the item restriction information.
(5) The control device according to the (3) or (4), wherein:
   the plurality of relay connection ports include a dedicated relay connection port; and
   the control device stores specific item information, the specific item information indicating specific items being items controllable only by using the operation terminal connected to the dedicated relay connection port via the terminal connection port among control items of the semiconductor manufacturing apparatus, for the dedicated relay connection port; and
   in a case where the operation terminal is connected to the dedicated relay connection port via the terminal connection port, other screen information indicating the specific items is transmitted to the operation terminal connected to the dedicated relay connection port via the relay device, based on the specific item information.
(6) The control device according to any one of the (1) to (5), wherein
   in a case where a plurality of the operation terminals are connected to the terminal connection ports, the module controlled via the operation terminal connected first is excluded from the information on the controllable modules included in the screen information when the screen information is transmitted to the operation terminal connected later, based on the module restriction information.
(7) The control device according to any one of the (1) to (5), wherein
   in a case where a plurality of the operation terminals are connected to the terminal connection ports, an operation on the operation terminal connected later related to the module controlled via the operation terminal connected first is disabled.
(8) A semiconductor manufacturing system including:
   the control device according to any one of the (1) to (7); and the semiconductor manufacturing apparatus.
(9) The semiconductor manufacturing system according to the (8), further including
   the operation terminal, wherein
   in the case where the operation terminal is connected to one of the terminal connection ports and the operation terminal is detected via the corresponding detector, the connected operation terminal displays the operation screen based on the screen information.
(10) A control method of controlling a semiconductor manufacturing apparatus having a plurality of modules by a control device based on an operation from a user on an operation terminal displaying an operation screen of the semiconductor manufacturing apparatus,
   the semiconductor manufacturing apparatus including:
      a plurality of terminal connection ports to which the operation terminal is to be connected; and
      a plurality of detectors for detecting the operation terminal connected to the terminal connection ports, the terminal connection ports also serving as the detectors or the detectors being provided around the terminal connection ports,
   the method including,
   in a case of the operation terminal being connected to one of the terminal connection ports and the operation terminal being detected via the corresponding detector:
   the control device transmitting screen information about the operation screen to the connected operation terminal based on module restriction information indicating controllable modules corresponding to the detectors in units of the detector; and
   the connected operation terminal displaying the operation screen based on the screen information, the screen information including information indicating the controllable modules corresponding to the detector used for the detection.
(11) The control method according to the (10), wherein:
   the terminal connection ports also serve as the detectors;
   the controllable modules corresponding to the terminal connection ports are recorded in units of the terminal connection port in the module restriction information; and
   in the transmitting in the case where the operation terminal is connected to one of the terminal connection ports, the screen information to be transmitted by the control device to the connected operation terminal includes information indicating the controllable modules corresponding to the terminal connection port to which operation terminal is connected.
(12) The control method according to the (11), wherein:
   the operation terminal connected to the terminal connection port and the control device are connected via a relay device;
   the relay device has a plurality of relay connection ports to be connected to the terminal connection ports;
   the module restriction information indicates controllable modules corresponding to the relay connection ports for each of the relay connection ports; and
   in the case where the operation terminal is connected to one of the terminal connection ports,
   in the transmitting, the control device transmits the screen information corresponding to the controllable modules corresponding to the relay connection port to which the operation terminal is connected via the terminal connection port, to the connected operation terminal via the relay device based on the module restriction information.
(13) The control method according to any one of the (10) to (12), wherein
   in the transmitting in the case where the operation terminal is connected to one of the terminal connection ports and the operation terminal is detected via the corresponding detector,
   the control device transmits the screen information including information indicating controllable items corresponding to an authority of the user to the connected operation terminal, based on an acquisition result of information on the authority of the user using the connected operation terminal and item restriction information indicating the controllable items corresponding to the authority of the user among control items of the modules for each authority of the user.
(14) The control method according to the (12) or (13),
   the plurality of relay connection ports including a dedicated relay connection port,
   the method further including,
   in a case of the operation terminal being connected to the dedicated relay connection port via the terminal connection port:
   the control device transmitting other screen information indicating specific items to the operation terminal connected to the dedicated relay connection port via the relay device, based on specific item information indicating the specific items being items controllable only by using the operation terminal connected to the dedicated relay connection port via the terminal connection port among control items of the semiconductor manufacturing apparatus, for the dedicated relay connection port; and
   the operation terminal connected to the dedicated relay connection port displaying the operation screen based on the other screen information.
(15) A computer-readable storage medium storing a program running on a computer of a control device to cause the control device to execute a control method of controlling a semiconductor manufacturing apparatus having a plurality of modules based on an operation from a user on an operation terminal displaying an operation screen of the semiconductor manufacturing apparatus,
   the semiconductor manufacturing apparatus including:
      a plurality of terminal connection ports to which the operation terminal is to be connected; and
      a plurality of detectors for detecting the operation terminal connected to the terminal connection ports, the terminal connection ports also serving as the detectors or the detectors being provided around the terminal connection ports,
   the method including,
   in a case of the operation terminal being connected to one of the terminal connection ports and the operation terminal being detected via the corresponding detector:
   the control device transmitting screen information about the operation screen to the connected operation terminal based on module restriction information indicating controllable modules corresponding to the detectors in units of the detector, the screen information including information indicating the controllable modules corresponding to the detector used for the detection.

According to this disclosure, it is possible to control a semiconductor manufacturing apparatus based on an operation of an operator on an operation terminal.

What is claimed is:

1. A control device for controlling a semiconductor manufacturing apparatus having a plurality of modules, the device for controlling the semiconductor manufacturing apparatus based on an operation from a user on an operation terminal displaying an operation screen of the semiconductor manufacturing apparatus,
the semiconductor manufacturing apparatus comprising:
a plurality of terminal connection ports to which the operation terminal is to be connected; and
a plurality of detectors for detecting the operation terminal connected to the terminal connection ports, the terminal connection ports also serving as the detectors or the detectors being provided around the terminal connection ports,
the control device being configured to:
store module restriction information, the module restriction information indicating controllable modules corresponding to the detectors in units of the detector; and
in a case of the operation terminal being connected to one of the terminal connection ports and the operation terminal being detected via the corresponding detector, transmit screen information about the operation screen to the connected operation terminal based on the module restriction information, the screen information including information indicating the controllable modules corresponding to the detector used for the detection.

2. The control device according to claim 1, wherein:
the terminal connection ports also serve as the detectors;
the controllable modules corresponding to the terminal connection ports are recorded in units of the terminal connection port in the module restriction information; and
in the case where the operation terminal is connected to one of the terminal connection ports, the screen information including information indicating the controllable modules corresponding to the terminal connection port to which the operation terminal is connected is transmitted to the connected operation terminal, based on the module restriction information.

3. The control device according to claim 2, wherein:
the control device is connected to the operation terminal connected to the terminal connection port via a relay device;
the relay device has a plurality of relay connection ports to be connected to the terminal connection ports;
the module restriction information indicates controllable modules corresponding to the relay connection ports for each of the relay connection ports; and
in the case where the operation terminal is connected to one of the terminal connection ports, the screen information including the information indicating the controllable modules corresponding to the relay connection port to which operation terminal is connected via the terminal connection port is transmitted to the connected operation terminal via the relay device, based on the module restriction information.

4. The control device according to claim 1, wherein:
the control device stores item restriction information, the item restriction information indicating a controllable item corresponding to an authority of the user among control items of the modules for each authority of the user; and
in the case where the operation terminal is connected to one of the terminal connection ports and the operation terminal is detected via the corresponding detector, the screen information including information indicating the controllable item corresponding to the authority of the user is transmitted to the connected operation terminal, based on an acquisition result of the information on the authority of the user using the connected operation terminal and the item restriction information.

5. The control device according to claim 3, wherein:
the plurality of relay connection ports include a dedicated relay connection port; and
the control device stores specific item information, the specific item information indicating a specific item being an item controllable only by using the operation terminal connected to the dedicated relay connection port via the terminal connection port among control items of the semiconductor manufacturing apparatus, for the dedicated relay connection port; and
in a case where the operation terminal is connected to the dedicated relay connection port via the terminal connection port, other screen information indicating the specific items is transmitted to the operation terminal connected to the dedicated relay connection port via the relay device, based on the specific item information.

6. The control device according to claim 1, wherein
in a case where a plurality of the operation terminals are connected to the terminal connection ports, the module controlled via the operation terminal connected first is excluded from the information on the controllable modules included in the screen information when the screen information is transmitted to the operation terminal connected later, based on the module restriction information.

7. The control device according to claim 1, wherein
in a case where a plurality of the operation terminals are connected to the terminal connection ports, an operation on the operation terminal connected later related to the module controlled via the operation terminal connected first is disabled.

8. A semiconductor manufacturing system comprising:
the control device according to claim 1; and
the semiconductor manufacturing apparatus.

9. The semiconductor manufacturing system according to claim 8, further comprising
the operation terminal, wherein
in the case where the operation terminal is connected to one of the terminal connection ports and the operation terminal is detected via the corresponding detector, the connected operation terminal displays the operation screen based on the screen information.

10. A control method of controlling a semiconductor manufacturing apparatus having a plurality of modules by a control device based on an operation from a user on an operation terminal displaying an operation screen of the semiconductor manufacturing apparatus,
the semiconductor manufacturing apparatus comprising:
a plurality of terminal connection ports to which the operation terminal is to be connected; and
a plurality of detectors for detecting the operation terminal connected to the terminal connection ports, the terminal connection ports also serving as the detectors or the detectors being provided around the terminal connection ports,
the method comprising,
in a case of the operation terminal being connected to one of the terminal connection ports and the operation terminal being detected via the corresponding detector:
the control device transmitting screen information about the operation screen to the connected operation terminal based on module restriction information indicating controllable modules corresponding to the detectors in units of the detector; and
the connected operation terminal displaying the operation screen based on the screen information, the screen information including information indicating the controllable modules corresponding to the detector used for the detection.

11. The control method according to claim 10, wherein:
the terminal connection ports also serve as the detectors;
the controllable modules corresponding to the terminal connection ports are recorded in units of the terminal connection port in the module restriction information; and
in the transmitting in the case where the operation terminal is connected to one of the terminal connection ports, the screen information to be transmitted by the control device to the connected operation terminal includes information indicating the controllable modules corresponding to the terminal connection port to which operation terminal is connected.

12. The control method according to claim 11, wherein:
the operation terminal connected to the terminal connection port and the control device are connected via a relay device;
the relay device has a plurality of relay connection ports to be connected to the terminal connection ports;
the module restriction information indicates controllable modules corresponding to the relay connection ports for each of the relay connection ports; and
in the case where the operation terminal is connected to one of the terminal connection ports,
in the transmitting, the control device transmits the screen information corresponding to the controllable modules corresponding to the relay connection port to which the operation terminal is connected via the terminal connection port, to the connected operation terminal via the relay device based on the module restriction information.

13. The control method according to claim 10, wherein
in the transmitting in the case where the operation terminal is connected to one of the terminal connection ports and the operation terminal is detected via the corresponding detector,
the control device transmits the screen information including information indicating a controllable item corresponding to an authority of the user to the connected operation terminal, based on an acquisition result of information on the authority of the user using the connected operation terminal and item restriction information indicating the controllable item corresponding to the authority of the user among control items of the modules for each authority of the user.

14. The control method according to claim 12,
the plurality of relay connection ports including a dedicated relay connection port,
the method further comprising,
in a case of the operation terminal being connected to the dedicated relay connection port via the terminal connection port:
the control device transmitting other screen information indicating a specific item to the operation terminal connected to the dedicated relay connection port via the relay device, based on specific item information indicating the specific item being an item controllable only by using the operation terminal connected to the dedicated relay connection port via the terminal connection port among control items of the semiconductor manufacturing apparatus, for the dedicated relay connection port; and
the operation terminal connected to the dedicated relay connection port displaying the operation screen based on the other screen information.
